(19) United States
(12) Patent Application Publication
(10) Pub. No.: US 2025/0096065 A1
(43) Pub. Date: Mar. 20, 2025

(54) METHOD OF MANUFACTURING A COOLING ARRANGEMENT AND COOLING ARRANGEMENT FOR POWER ELECTRONIC COMPONENTS

(71) Applicant: Miba Sinter Austria GmbH, Laakirchen (AT)

(72) Inventors: Manuel Pohn, Zell am Pettenfirst (AT); Juergen Bauer, Altmuenster (AT)

(21) Appl. No.: 18/774,912

(22) Filed: Jul. 16, 2024

(30) Foreign Application Priority Data
Jul. 27, 2023 (AT) A50603/2023

(51) Int. Cl. H01L 23/367; B23K 26/242; H01L 23/373

(52) U.S. Cl. CPC H01L 23/3675; B23K 26/242; H01L 23/3736

(57) ABSTRACT

A cooling arrangement and method of manufacturing a cooling arrangement for power electronic components are disclosed. The method includes provisioning a powder-metallurgical substance and forming or pressing the substance to a green compact; sintering the green compact to a preform; shaping the preform to a cooling device with an enlarged-surface cooling structure, the enlarged-surface cooling structure comprises a plurality of cooling projections, the cooling projections formed via a pressure-loadable die by pressing a sub-section of the preform into form-defining recesses of the die while a base section remains, the base section connects the individual cooling projections; and jointing the cooling device via a material bond to a metal cast component by welding or soldering.

### CROSS-REFERENCE TO RELATED APPLICATION

This application claims priority to Austrian Application No. AT A50603/2023 filed on Jul. 27, 2023, the contents of which are hereby incorporated by reference in its entirety.

### TECHNICAL FILED

The invention relates to a method of manufacturing a cooling arrangement for power electronic components, comprising the steps provisioning a powder-metallurgical substance and forming or pressing the substance to a green compact, sintering the green compact to a preform, and shaping the preform to a cooling device with an enlarged-surface cooling structure.

Further, the invention relates to a cooling arrangement for cooling power electronic components, comprising a cooling device as a mounting platform for at least one power electronic component, which cooling device is further affixed at a metal component, wherein the cooling device has a first surface at its base section for mounting the at least one power electronic component and a second surface of the base section is equipped with a cooling structure, having cooling projections, opposite the first surface.

### BACKGROUND

So-called power electronics components, such as power semiconductors, are sufficiently known from the prior art. Such components are used often, for example also in motor vehicles. It is further known that these components generate large amounts of heat in operation, which must often be discharged with the help of a cooling medium. For this purpose, the most varied coolers are known in the prior art.

For example, DE 11 2007 000 829 B4 describes an arrangement of an inverter and a cooler for cooling the inverter, wherein the cooler comprises the following: a substrate, which has a surface on which the inverter is arranged; heat release components, which are affixed at another, opposite surface of the substrate and surround a region located opposite a region in which the inverter is arranged on the one surface of the substrate; a main pipe, which is located remote from the other surface of the substrate and limits a space located between the main pipe and the substrate and configured such that a cooling means can be supplied to it and it enables the cooling means to come into contact with the heat release components; and a side pipe, which protrudes from the main pipe towards substrate and is located opposite the region of the substrate in which the inverter is arranged, so that it allows for a cooling means supplied to the main pipe to hit the other surface of the substrate at the region which is located opposite the region in which the inverter is arranged, wherein the cooling means supplied to the main pipe is separated from the cooling means supplied to the space until it is emitted from the side pipe.

Also so-called pin-fin cooling elements have been described in the prior art, around which a cooling medium flows and which thus transfer the heat from the pins to the cooling medium. For example, DE 10 2019 108 106 A1 describes a cooler for a power semiconductor in an inverter, wherein the cooler is designed in two parts and comprises: a bottom plate as a first part, which is linkable to the power semiconductor so as to conduct heat; a cooling element as a second part, which is arranged at the bottom plate, wherein the cooling element has at least one wave-like recess, which is configured so as to be continuous from a side of the cooling element facing away from the bottom plate up to a side facing the cooling element; wherein the first and second parts are interconnected and coated by means of a layer which protects both parts from electrochemical reduction.

A device for cooling components is known from DE 10 2018 216 859 A1, having: a first and a second base body; cylindrical and/or cone-shaped first cooling fins configured in the first base body, around which a cooling means can flow, and cylindrical and/or cone-shaped second cooling fins configured in the second base body, around which the cooling means can flow, wherein the second base body is jointed with the first base body such that the second cooling fins are located between the first cooling fins without touching the first base body.

Cooling devices for the power electronics unit often have a structure of elevations on their surface. A surface with elevations that is as large as possible and around which a cooling fluid can flow is of advantage for increasing the cooling performance. However, this surface is limited by the mechanical strength of the elevations, as the elevations can be reduced only down to a minimum size in their cross sections. The cross-sectional reduction in size of the elevations enables more elevations per unit of area to be arranged, whereby the cooling performance can be improved due to the larger surface thus provisioned.

### SUMMARY

The object underlying the present invention is to improve the cooling performance of a cooling arrangement for power electronic components, wherein the cooling arrangement is to be manufactured in a resource-saving manner.

The object of the invention is achieved by a method of manufacturing a cooling arrangement for power electronic components which comprises the following steps:
provisioning a powder-metallurgical substance and forming or pressing the substance to a green compact,
sintering the green compact to a preform,
shaping the preform to a cooling device with an enlarged-surface cooling structure, which enlarged-surface cooling structure comprises a plurality of cooling projections, which cooling projections are formed by means of a pressure-loadable die by pressing a sub-section of the preform into form-defining recesses of the die while a base section remains and/or is held back, which base section connects, in particular supports and/or holds together as one piece, the individual cooling projections and
jointing the cooling device by means of a material bond to a metal cast component by welding, in particular laser welding, or soldering.

Further, the object of the invention is achieved with a cooling arrangement for cooling power electronic components, which cooling arrangement comprises a cooling device as a mounting platform for at least one power electronic component, which cooling device is further affixed at a metal component, wherein the cooling device has a first surface at its base section for mounting the at least one power electronic component and has and/or defines a second surface with a cooling structure, having cooling projections, opposite the first surface, wherein the base section and the cooling projections consist of a sintered substance, wherein the cooling projections are manufactured by shaping from the substance and/or material of the base section, wherein the metal component is a cast component, and wherein the base section of the cooling device is jointed, by means of a material bond, to the metal cast component by welding, in particular laser welding, or by soldering and, due to said jointing by means of a material bond, a liquid-tight bond is simultaneously established between the cooling device and the cast component.

It is of advantage here that, due to the shaping of the sintered preform to the cooling device with the cooling projections, their manufacture produces no waste material, unlike machining, for example. In addition, all cooling projections of the cooling device can be manufactured at the same time, thereby achieving a corresponding increase in productivity. Here, it is advantageous for the shaping that the preform, despite already having a predetermined strength due to the sintering, is easier to form in comparison to a solid material due to pores. The shaping process ensures that a cooling device with a larger surface can be provisioned, whereby the cooling performance of the cooling device can be improved.

The component combination of the powder-metallurgically manufactured cooling device, which can also be referred to as primary cooling element, and of the metal cast component results in an improved-performance cooling arrangement for power electronic components, for example for semiconductor components. The relatively high thermal conductivity of the powder-metallurgically manufactured cooling device in comparison to the cast component ensures that a swift and intensive heat discharge from power electronic components can be achieved. The material bond of the cooling element with the metal cast component supports a thermal heat-transfer resistance that is as low as possible and thus improves the onward discharge of the thermal energy to the metal cast component. A cooling arrangement manufactured according to the specified method has a favorable cooling performance and cooling characteristic for power electronic semiconductor components. Other than performance-related advantages, the multi-part cooling arrangement jointed as one piece also has advantages in terms of production engineering, such as a serial production that is as low in cost as possible and yet quality-oriented, for example.

In accordance with an advantageous embodiment, it can be provided that the cooling projections are formed by means of the recesses in the die so as to be cylindrical or cone-shaped. This ensures that easily and/or consistently reproducible cooling projections can be achieved with application of form-defining pressures that are as low as possible. Undesired malformation of the cooling projections can be impeded as sharp edges, corners or acutely-angled sections are avoided and/or minimized.

In accordance with an alternative design, the cooling projections can have the shape of rhombi, triangles, ellipses, teardrops and suchlike in relation to the cross section of their height axis.

In accordance with an advantageous embodiment variant, it can be provided that a cavity for a cooling medium is defined or limited, at least in sections, by the metal cast component and that the cooling device is inserted in a wall opening of the metal cast component and this wall opening is closed by the cooling device so as to be liquid-tight without a separate and/or additional sealing element. This ensures that the cooling arrangement is highly functional and efficient and yet manufacturable as low in cost as possible. The redundancy of a separate sealing element has advantages in terms of production engineering and can facilitate long-term stability of the tightness. In addition, it facilitates the achievable cooling performance of the cooling arrangement. In particular, also highly efficient electronic semiconductor components with high cooling requirements can be tempered reliably.

In accordance with another embodiment variant of the invention, it can be provided that the cooling device has a rabbet, in particular a so-called single rabbet, on its circumference, which rabbet is manufactured by shaping with said die or with another die and is configured and/or used to be in contact with boundary sections of a wall opening of the metal cast component. Such a rabbet can be manufactured relatively simply and with relative dimensional accuracy in the course of the form-defining process of the cooling device. Complex reworking is often obsolete. This dimensional accuracy is favorable for the tightness of the joint and for a process-reliable procedure when jointing, by means of a material bond, the cooling device to the metal cast component.

Further, it can be provided in the manufacturing method that the boundary sections of the wall opening are machined before the jointing, by means of a material bond, with the cooling device, so that an even contact surface for the cooling device is created. This can optimize and/or facilitate both the tightness of the joint and the heat transfer capacity between the cooling device and the cast component, so that an improved cooling arrangement can be achieved.

According to one embodiment of the invention, it can be provided that end sections of the cooling projections facing away from the base section protrude into the cavity of the metal cast component and that the power electronic component is affixed to the first surface of the base section facing away from the cooling projections. The surface-enlarging cooling structure of the cooling device is thereby exposed to the cooling medium, for example to a cooling liquid, and/or the cooling medium flows around it. The first surface of the base section facing away from the cooling projections can be manufactured with a sufficiently even surface in the course of the pressing and sintering operation, so that a good heat transfer between the power electronic component and the powder-metallurgically manufactured cooling device can be ensured.

In accordance with a further measure, it can be provided that a laser beam welding device is used for the jointing by means of a material bond, with which laser beam welding device a fillet weld between a circumferential lateral surface of the cooling device and the cast component is manufactured. This ensures that a process-reliable large-scale production can be achieved and a reliably sealing bond between the cooling device and the cast component can be achieved. This ensures that tolerances and/or varying gap dimensions have hardly any and/or relatively little influence on the quality of the welded bond.

It can also be expedient if the shaping of the preform to the cooling device is carried out in multiple shaping steps. This ensures that a high quality and/or dimensional accuracy of the cooling device can be achieved, whereby the jointing operation, by means of a material bond, for creating the cooling arrangement can be executed in a process-reliable manner. Furthermore, low maximum pressing forces can be achieved when using gradually adapted dies that are each shaped differently, and an energy-efficient, resource-saving manufacture can consequently be achieved.

The cooling projections at the second surface of the base section can be configured cylindrical or cone-shaped. Such cooling projections can be manufactured in a relatively process-reliable and/or with relatively accurate repeatability by compression forming sintered material. This is true in particular when the sintered material and/or the preform comprises relatively soft metals, in particular comprises more than 97.5 vol.-% aluminum or more than 99 vol.-% copper.

An efficient cooling arrangement that is as low cost as possible as well as resource-saving can be created by means of an embodiment in which the metal cast component defines or limits, at least in sections, a cavity for a cooling medium and the cooling device is inserted in a wall opening of the metal cast component and this wall opening is closed by the cooling device so as to be liquid-tight without a separate sealing element.

An efficient, robust and simultaneously resource-saving and/or weight-optimized, in particular lightweight, cooling arrangement can further be created in that the cooling device has a rabbet at its circumference, which rabbet rests against boundary sections of a wall opening of the metal cast component so as to transmit load and conduct heat.

In accordance with another embodiment, the cast component can be an aluminum diecast component and the sintered substance of the cooling device can comprise predominantly aluminum or predominantly copper. This pairing of components ensures that advantageous interactions are achieved in relation to cooling performance, cost efficiency and manufacturability.

Further, it can be provided that at least individual of the cooling projections have a higher density in their head sections facing away from the base sections than the remaining cooling projections and/or that at least individual of the cooling projections have a different form in the head sections than the remaining cooling projections. A height calibration and/or height adjustment of the cooling projections is efficiently achievable and/or easily realizable by means of a die on which a force is exerted. This ensures that cooling projections are made available which can be better adapted to the respective area of application.

For the purpose of better understanding of the invention, it will be elucidated in more detail by means of the figures below.

### BRIEF DESCRIPTION OF THE DRAWINGS

The figures show in a respectively very simplified schematic representation:

FIG. 1 a cooling device with a component to be cooled in a side view;

FIG. 2 a cooling device in an oblique view;

FIG. 3 an embodiment variant of a preform;

FIG. 4 an embodiment variant of a tool for manufacturing the cooling device;

FIG. 5 an embodiment of the multi-part cooling arrangement as one piece in a sectional representation;

FIG. 6 another embodiment of the multi-part cooling arrangement as one piece in a sectional representation;

FIG. 7 a detail from a tool for adjusting the height of the cooling projections.

### DETAILED DESCRIPTION

First of all, it is to be noted that, in the different embodiments described, equal parts are provided with equal reference numbers and/or equal component designations, where the disclosures contained in the entire description may be analogously transferred to equal parts with equal reference numbers and/or equal component designations. Moreover, the specifications of location, such as at the top, at the bottom, at the side, chosen in the description refer to the directly described and depicted figure, and in case of a change of position, these specifications of location are to be analogously transferred to the new position.

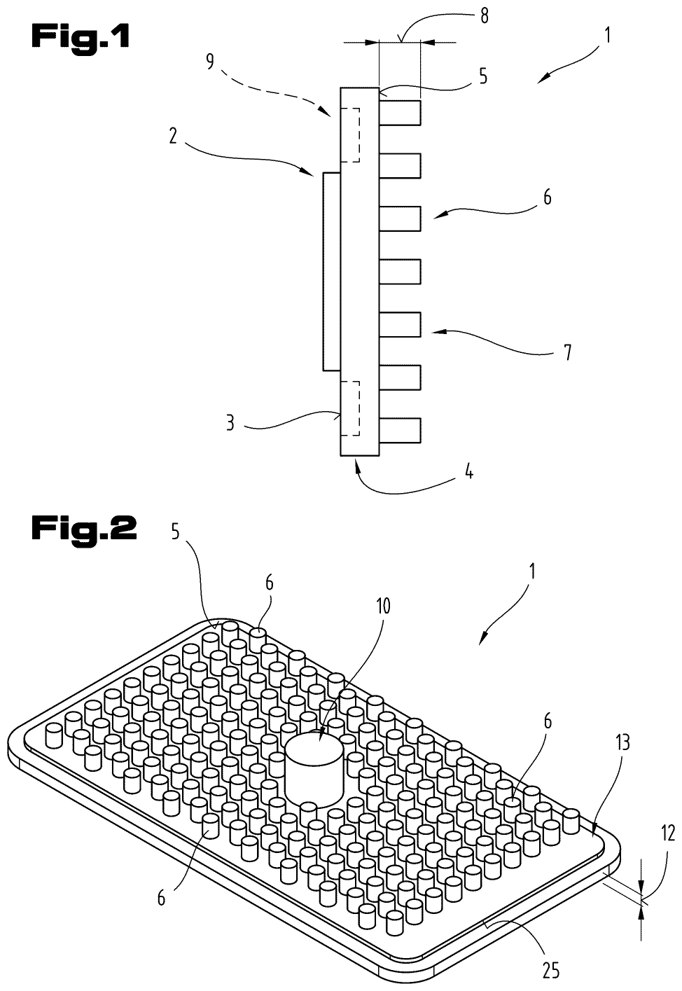

FIG. 1 shows is a cooling device 1 in a side view.

The cooling device 1 serves the cooling of a component 2 or of multiple components 2 and/or of a module. To that end, the cooling device 1 rests with a first surface 3 against the at least one component 2, in particular immediately, i.e. it is preferably in direct contact with the component 2 so as to exchange heat.

The component 2 is preferably an electronic component, in particular a so-called power electronics component and/or high power electronics component or a power semiconductor and/or high power semiconductor, but it can also be configured differently. In particular, such components 2 and/or modules of/with these components 2 can be provided for a power in the region of multiple kW up to MW. Such components 2 serve, for example, to convert electric energy with switching, electronic elements. Typical applications are converters or frequency converters in the field of electrical drive engineering, solar inverters and converters for wind turbines for feeding regeneratively generated energy in the power grid or switching-mode power supplies, generally the conversion of AC voltage to DC voltage by means of rectifiers, the conversion of DC voltage to AC voltage by means of inverters, controllers, for example in the drive system of an electric drive in electric vehicles and/or hybrid vehicles, battery management systems, etc. Examples of a power electronics component include a semiconductor, in particular a so-called power semiconductor, e.g. an IGBT.

As such components 2 per se are known from the relevant prior art, reference shall be made, in this context, to this prior art in order to avoid repetition in relation to details.

The cooling device 1 comprises a base section 4, which also forms the rear side and/or first surface 3 of the cooling device 1, and which base section 4 has and/or forms a cooling structure on a second surface 5, which is located opposite the first surface 3. In particular, the for example cuboid or plate-like base section 4 of the cooling device 1 forms the cooling structure at its second surface 5. The cooling structure is formed by cooling projections 6, which are arranged at the base section 4 so as to protrude beyond the second surface 5 and are connected thereto as one piece, as can also be seen from FIG. 2. In other words, the cooling device 1 is formed by only a single piece in the preferred embodiment variant. Irrespective of this single-piece configuration, it is possible within the scope of the invention that multiple cooling devices 1 corresponding to the invention can be combined with one another to a cooling device group per component 2 and/or module of/with at least one such component 2. In particular, multiple cooling devices 1 can therefore be put together, also modularly, to a cooling device group.

The base section 4 and the cooling projections 6 are manufactured from a sintered substance and/or consist thereof. Further, the cooling projections 6 are manufactured from the base section 4 by shaping, in particular formed by mechanical shaping from the material of the base section 4, preferably without machining.

In the preferred embodiment variant, the base section 4 and the cooling projections 8 have a density of at least 98%, in particular at least 98.5%, preferably at least 99%, of the full density of the substance used.

Here, the full density relates to the density of a cooling device from the same melting-metallurgically manufactured substance, i.e. a component from a solid substance. Here, solid substance means a metal substance which—with the exception of faults—has no pores such as they usually exist in sintered components.

The cooling projections 6 are provided such that a cooling medium, for example water, flows around them, so that the heat absorbed by the cooling device 1 is transported away via this cooling medium. In a preferred manner, the cooling device 1 is configured as a so-called pin-fin cooling device.

The cooling projections 6 of the embodiment variant represented are preferably configured cylindrical or in the shape of a truncated cone. However, they can also have a different shape, for example have another cross section tapering off in a direction towards a cooling projection head 7, for example have a truncated-pyramid appearance. In accordance with an embodiment variant, multiple or all cooling projections 6 in the head region can be configured mushroom-shaped, as indicated by a dashed line in FIG. 7.

The cross section of the cooling projections 6—with respect to their height 8 relative to the base section 4—can be circular, oval, rhomboid, square, in the shape of a teardrop, etc.

Further, all cooling projections 6 can be configured identical. However, it is also possible to arrange and/or to combine cooling projections 6 with different shapes on a base section 4.

The cooling projections 6 can preferably have a height 8 above the second surface 5 of the base section 4 which is between 2.5 mm and 40 mm.

In the simplest design of the cooling device 1, any and all cooling projections 6 of the cooling device 1 have the same height 8 within the tolerances. However, it is also possible within the scope of the invention that a part of the cooling projections 6 has a lower height than the remaining cooling projections 6.

Further, it can be provided that between 300 and 1300, in particular between 300 and 1000, for example between 300 and 750, cooling projections 6 are arranged and/or configured per dm² of the second surface. This particular number has proven advantageous with respect to the manufacture of the cooling device 1, i.e. the shaping of the base section 4 and/or of the preform 11 to the cooling projections 6, as it ensures that damage to the cooling projections 6 and/or incompletely configured cooling projections 6 can be avoided and/or reduced.

As can be seen in particular from FIG. 1, it can be provided in accordance with an embodiment variant of the cooling device 1 that the first surface 3 of the base section 4 is configured with an even surface. However, it is also possible that the first surface 3 is configured with one or multiple depressions 9, in which a component 2 is at least partially received. This ensures that a better connection of the component 2 to the cooling device 1 can be achieved. Generally, the component 2 can, for example, be glued or screwed or soldered or sintered, etc., to the cooling device 1.

The at least one depression 9 can be manufactured during the manufacture of the cooling projections 6 simultaneously with same. The application and/or configuration of the at least one depression 9 at the first surface 3 also enables the manufacture of cooling projections 6 whose height 8 is greater than that of the remaining cooling projections 6.

As apparent from FIG. 2, the cooling device 1 can have at least one other structural element 10 configured as an elevation on the second surface 5 of the base section 4. In the form represented, the structural element 10 is a cylinder, but it can also have a different cross-sectional area, for example a rhomboid one. Another area can be made available on the cooling device 1 by the structural element 10, which area is located above the level of the cooling projections 6. The structural element 10 can also have a greater height than the cooling projections 6. However, it is also possible that the at least one structural element 10 has a smaller, or the same, height as the cooling projections 6. Further, more than one structural element 10 can be arranged, wherein the multiple structural elements 10 can be configured identical or different, e.g. in shape and/or height.

The structural element 10 can be provided, for example, for a screw connection, as a reinforcement or as a spacer or as a stop.

The structural element 10 is preferably not reworked mechanically but is pressed and/or powder-metallurgically manufactured in net shape quality or near net shape quality during the pressing of a preform 11 for the manufacture of the cooling device 1. The structural element 10 and/or the structural elements 10—just like the cooling projections 6—are therefore configured preferably as one piece and/or integral with the base section 4.

To manufacture the cooling device 1, a sintering powder and/or a powder used in powder metallurgy, in particular a metal powder, is used. In a preferred manner, a sintering powder which has a correspondingly good thermal conductivity is used. In particular, a sintering powder on the basis of aluminum and/or of an aluminum alloy or on the basis of copper and/or of a copper alloy or an MMC (metal-matrix composite) powder which contains copper or aluminum powder is used.

The manufacture of the cooling device 1 is done using powder metallurgy according to a powder-metallurgical method. The cooling device 1 is also preferably a sintered component. To that end, a green compact is manufactured in a corresponding press mold (matrix) from a sintering powder, which can be manufactured from the individual (metal) powders by mixing, wherein the powders can optionally be used pre-alloyed. Preferably, the green compact has a density of at least 80%, in particular between 90% and 96%, of the full density of the material.

The green compact can subsequently be dewaxed at usual temperatures and single-stage or double-stage and/or multi-stage sintered and afterwards be cooled preferably to room temperature. The sintering can be done, for example, at a temperature between 500° C. and 1300° C.

As these methodologies and the method parameters used therein are also known from the prior art, reference shall be made, in this context, to the relevant prior art in order to avoid repetition.

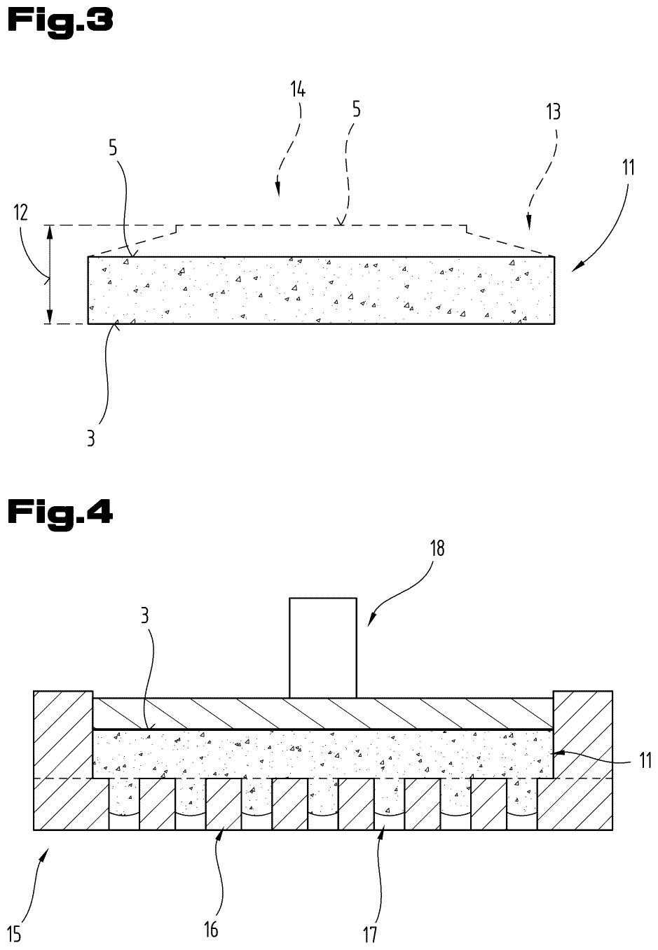

The sintering results in the green compact becoming a preform 11 as represented in FIG. 3 by way of example. The preform 11 can be configured as a flat plate and/or plate-like, so that the first surface 3 and at least one section of the second surface 5 can therefore run parallel to each other.

According to one embodiment variant of the method, it can be provided that the second surface 5 of the preform 11, on which the cooling structure is configured, is manufactured cambered, at least in sections. Generally, the preform 11 can be manufactured with a different thickness 12, at least in sections. In particular, the preform 11 can be manufactured thinner in at least one peripheral section 13, or in multiple peripheral sections 13, than in a center section 14, as represented in dashed lines in FIG. 3. Here, the center section 14 is the region of the preform 11 that has the greatest thickness 12. The thinner peripheral sections 13 can be configured, for example, circumferential around the center section 14, i.e. along the entire circumference of the center section 14. The reduction of the thickness 12, starting from the center section 14, can be configured abrupt and/or ramp-like, as also represented in FIG. 3. Other forms are also possible.

The reduced thickness 12 in at least one peripheral section 13 can also still be provided at the finished cooling device 1 as a shoulder and/or rabbet 25, as can be seen from FIG. 2 or from FIG. 6.

Other forms of the second surface 5 of the preform 11 are possible with respect to an improved formability of the preform 11. For example, first pin-fin rudiments and/or cooling projection rudiments (circular, oval, ellipse-like, drop-like and/or wart-like, etc.) with a height between 0.1 mm and 2.0 mm can already be preformed at the preform 11. In addition, structures (waves, fins, etc.) can purposely be inserted in the second surface 5 of the preform 11 in order to optionally increase swirling of a cooling medium flowing past.

The preform 11 can subsequently be recompressed. However, the recompression is preferably done simultaneously with the shaping of the preform 11 to the cooling device 1 with the cooling projections 6.

The shaping of the preform 11 for creating the cooling structure with the plurality of cooling projections 6 is done in a die 15. To that end, the preform 11 is inserted in the die 15 or brought in flush contact with same. In the simplest case, the die 15 comprises a perforated plate 16. The perforated plate 16 has recesses 17, in particular openings, in which and/or through which a part of the material of the preform 11 is pressed, whereby the cooling projections 6 are formed. The remaining material of the preform 11, which is not pressed in or through the recesses 17 of the die 15, forms the base section 4 of the cooling device 1.

The recesses 17, i.e. their cross sections, are correspondingly adapted to the cross sections of the cooling projections 6 to be manufactured.

The die 15 can also look differently, i.e. it need not necessarily be a simple perforated plate 16. In particular, the die 15 can be configured “pot-like” as a matrix.

In case at least one other structural element 10 is provided, same can also be taken into account by a corresponding recess and/or a corresponding opening in the die 15.

For the shaping operation, a stamp 18 can be brought in flush contact with the first surface 3 of the preform 11, which also forms the first surface 3 of the base section 4, and pressed onto the preform 11 with a predeterminable pressure. The pressure exerted on the preform 11 ensures that material of the preform 11 is pressed into the recesses 17 and/or openings of the die 15. The shaping can be done, for example, at a pressure between 700 MPa and 1600 MPa. Further, the shaping can be done during a time of up to 10 seconds, in particular between 0.1 seconds and 10 seconds. Further, the shaping is preferably done at room temperature (20° C.), i.e. cold. Alternatively, the shaping can also be done after preheating the preform 11 to a temperature between 50° C. and 300° C., for example between 50° C. and 150° C., and/or in/with a die 15 heated to a temperature between 50° C. and 300° C., for example between 50° C. and 150° C.

It can be provided that the shaping of the preform 11 to the cooling structure and/or to the cooling device 1 is executed in multiple stages, i.e. carried out in two or multiple steps. For example, the shaping method can comprise two or more shaping steps until the cooling projections 6 are configured. In particular, three or four or five, etc., shaping steps with the same die 15, or different dies 15 in phases, can be provided to manufacture the cooling projections 6.

It should be mentioned in this context that the multi-stage shaping means the shaping of the preform 11 to the cooling projections 6 and not other shaping operations which are optionally also carried out, such as, for example, the calibration of the cooling projections 6, as will be stated below.

The multi-stage shaping can be carried out in the individual shaping steps with at least approximately consistent degrees of shaping. For example, the cooling projections 6 can undergo at least approximately the same height modification in each of the shaping steps. However, it is also possible that the degrees of shaping are distinct from one another in the individual shaping steps. For example, the height modification of the cooling projections 6 in a first shaping step can be greater than in a subsequent shaping step, or, vice versa, the height modification of the cooling projections 6 in a first shaping step can be smaller than in a subsequent shaping step.

The parameters for the shaping can be identical or different in the individual shaping steps. For example, the pressure exerted on the preform 11 can be greater in a first shaping step than in a subsequent shaping step. The parameters for the shaping can be selected from the above-mentioned ranges in the individual shaping steps.

In case of a two or multi-stage shaping method of shaping the cooling projections 6, the cooling projections 6 can be formed from the preform 11 with a first partial height with the die 15, for example said perforated plate 16, in a first shaping step. The first partial height is smaller than the height 8 of the cooling projections 6 after the second shaping step. The first partial height can be, for example, in the range between 20% and 80% of the height 8.

After the defining of the form, i.e. the shaping of the preform 11, the cooling device 1 can be finished. However, is also possible to rework the cooling device 1, in particular to calibrate the cooling device 1, as will be described below.

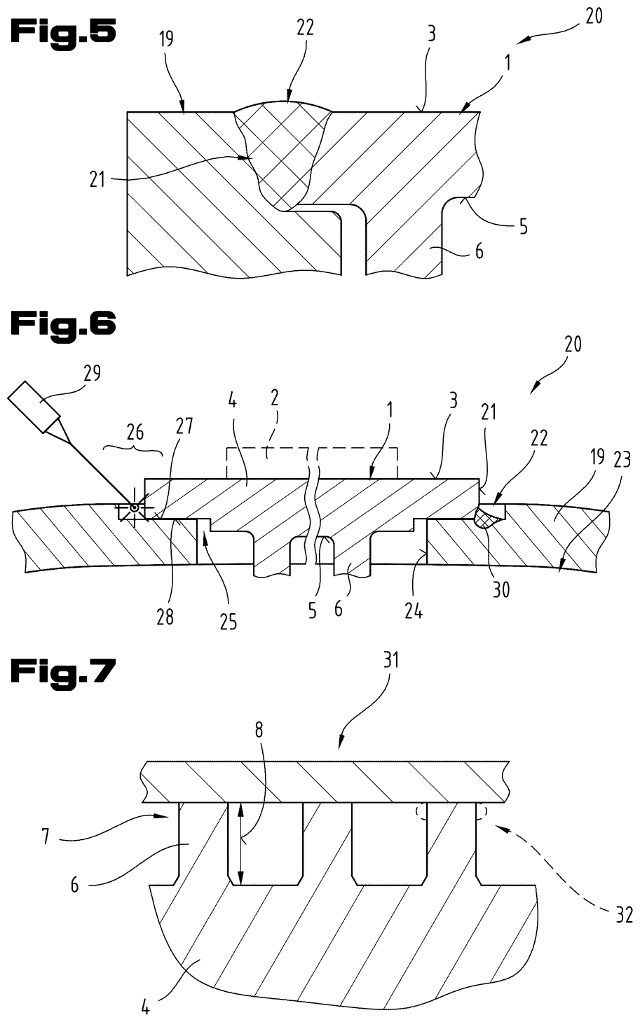

The cooling device 1 formed from metal sintered material by a powder-metallurgical method is subsequently joined to a metal cast component 19 by means of a material bond, as schematically illustrated in FIG. 5 or 6. This cast component 19 can be a diecast component from aluminum and/or from an aluminum alloy. The cast component 19 can be a housing part, for example in a drivetrain, or part of a support structure, for example of a support platform. The material-bond joint between the sintered and shaped cooling element 1 and the cast component 19 is formed by welding, in particular laser welding, or by soldering. This creates a multi-part cooling arrangement 20 jointed as one piece for power electronic components 2.

The jointing process with the cast component 19 can be done after the cooling device 1 is finally produced, in particular finally formed.

In accordance with the embodiment according to FIG. 5, the cooling device 1 is connected, by means of a material bond and by means of its narrow or lateral surfaces 21, which extend between the first and second surfaces 3, 5, to the cast component 19 by a weld seam 22 or alternatively by soldering material. The weld seam 22 can be formed by a welding wire substance.

Preferably, the weld seam 22 is formed exclusively by partially melting the material of the cast component 19 and by partially melting the material of the cooling device 1, i.e. without adding a welding substance, as represented in FIG. 6.

The cast component 19 can define, in particular spatially limit, a cavity 23 for a cooling medium. The cavity 23 can carry an in particular circulating cooling medium, for example oil or water, in a defined manner.

A wall opening 24 can be configured in the cast component 19. This wall opening 24 is dimensioned such that it is closed so as to be liquid-tight by the cooling device 1 inserted therein and by the weld seam 22. The joint between the cooling element 1 and the cast component 19 is configured without an additional sealing element, in particular configured liquid-tight only by the weld seam 22. Accordingly, the cooling device 1 is welded together with the cast component 19 so as to be sealing or soldered together with the cast component 19 so as to be sealing in order to form the cooling arrangement 20. The connection between the sintered and compression formed cooling device 1 and the cast component 19 is in particular realized so as to be screwless and sealless, whereby a low-cost production for a highly efficient cooling arrangement 20 can be achieved.

As illustrated by way of example in FIGS. 2 and 6, the cooling device 1 can have a rabbet 25, in particular a single rabbet, at its circumference and accordingly form a so-called shoulder. The rabbet 25 can rest against boundary sections of the wall opening 24 of the metal cast component 19 so as to transmit load and conduct heat. Mutually plane-parallel contact surfaces 27, 28 can be configured in boundary sections 26 of the wall opening 24 and in the rabbet 25 of the cooling device 1, which mutually plane-parallel contact surfaces 27, 28 contact each other in the jointed state of the cooling device 1 and of the cast component 19.

The boundary section 26 all around the wall opening 24 can be machined, for example flat milled, in order to form the contact surface 27 for the cooling device 1 with sufficient flatness. This ensures that a good heat transfer between the cooling device 1 and the cast component 19 as well as a reliable tightness of the weld or solder joint can be achieved. As can be seen in FIG. 6, the machining of the cast component 19 can result in an offset and/or rabbet or also be configured as a tapering-off, non-stepped contact surface 27.

The weld seam 22 preferably configured circumferential and uninterrupted around the cooling device 1 and/or along the wall opening 24 can be manufactured by a laser-beam welding device 29. The weld seam 22 can be configured at the cast component 19 as a fillet weld 30 between a circumferential lateral surface 21 of the cooling device 1 and the contact surface 27. This ensures that a process-stable and time-optimized production as well as a reliable tightness without the requirement of a separate sealing element can be achieved.

The cast component 19 can be an aluminum-diecast component and the sintered substance of the cooling device 1 can comprise predominantly aluminum or predominantly copper. The content of pure aluminum or pure copper in the cooling device 1 can be particularly high due to the configuration as a powder-metallurgically manufactured component, in particular be more than 97.5 vol.-% aluminum and/or more than 99 vol.-% copper of the total materials contained in the cooling device 1. The high degree of metal purity of the sintered and compression formed cooling device 1, in particular in relation to its aluminum or copper contents, ensures that a relatively high thermal conductivity and/or a relatively high cooling performance of the powder-metallurgically manufactured cooling device 1 in comparison to continuously extruded cooling elements or cooling elements manufactured with the casting method can be achieved.

End sections of the cooling projections 6 facing away from the base section 4 can protrude into the cavity 23 of the metal cast component 19, so that a cooling medium located in the cavity 23 can flow around them. The power electronic component 2 can be affixed to the first surface 3 of the base section 4 facing away from the cooling projections 6, which power electronic component 2 is thus bounded against the cavity 23 so as to be liquid-tight but is in heat-conductive connection with this cooling medium.

As illustrated in FIG. 7, it can be provided that the cooling device 1 is calibrated after the defining of the form by means of the at least one die 15 (FIG. 4), i.e. after the shaping of the preform 11. The calibration increases the dimensional accuracy of the cooling device 1 at least in sections and/or regions. In addition, the calibration ensures that the pores in the region of the calibrated surface can be closed, whereby a denser structure can therefore be achieved. During calibration, the cooling structure, in particular at least individual of the cooling projections 6, is/are exposed to a pressure on the respective surface(s).

In accordance with a preferred embodiment variant, a height calibration of the cooling projections 6 can be done, as represented in FIG. 7. Here, a calibration tool 31, which can be configured, for example, plate-like and/or stamp-like, can be used to exert pressure from above onto the cooling projection heads 7. During this operation, the cooling device 1 can be held in a holding element, such as a matrix, for example. The height deviation after the multiple shaping steps can be, for example, decreasing in a direction towards the center section 14 of the cooling device 1 (see FIG. 3) until a tolerable tolerance range of the height difference and/or of the heights 8 of the cooling projections 6 is achieved. Unless a part of this height difference has already been taken into account by the shape of the preform 11 (for example by forming regions with different thicknesses 12, for example following a curve shape), the calibration can be done in a correspondingly comprehensive manner. A preform 11 that already takes a height deviation of the sintered and shaped green compact at least partially into account can reduce the calibration work, i.e. the calibration effort.

The calibration tool 31 can also have mold cavities, in which the cooling projections 6 are at least partially received during calibration.

The calibration can be single or multi-stage, optionally with an intermediate relief of the strain on the cooling device 1 between the calibration steps.

According to an embodiment variant, it can also be provided that the heights 8 of the cooling projections 6 are adjusted by the pressing of material from the head region of the cooling projections 6 (the cooling projection heads 7) to a region 32 next to or below the head region of the cooling projections 6. This is represented in an exaggerated manner in FIG. 7. A simple plate tool, in particular the above-mentioned calibration tool 31, which is pressed against the cooling projections 6 can be used for the pressing.

It can be advantageous for the calibration and/or pressing of material if the cooling projections 6 have a height difference between a maximum of 0.2 mm and a maximum of 0.4 mm after the shaping, i.e. are manufactured with relatively small height differences. This can be done, for example, with the above-mentioned taking into account of the shape of the preform 11. The final height tolerance can be achieved more simply in a subsequent processing step by means of height calibration.

The calibration ensures that a machining of the cooling projections 6 for reducing the height tolerance of the cooling projections 6 can be avoided. The kind of the reduction of the height tolerance can result in partially mushroom-shaped or (slightly) bulging cooling projections 6, which can also be of advantage with respect to the flowing of a cooling medium flowing around the cooling projections 6 and therefore in relation to the cooling performance of the cooling device 1. In addition, the reduction of the height tolerance ensures that a remaining porosity at the top end of the cooling projections 6 can also be reduced and/or eliminated.

As stated above, the cooling device 1 can also have cooling projections 6 with mutually different heights 8. In order to be able to carry out a height calibration also in this case, the calibration tool 31 can be configured corresponding to the desired height curve of the cooling projections 6, for example graduated.

Also a correspondingly configured calibration tool 31 can be used for forming specific shapes of the cooling projections 6. To that end, the calibration tool 31 can have a mating contour in order to form, for example, the heads of the cooling projections 6 accordingly, i.e. equip them with a contour and/or surface design, such as, for example, a rounding, a chamfer, etc., or with a depression, a surface roughness which is greater than the roughness after the sintering, etc.

In case cooling projections 6 with different heights are configured, also a stepped calibration tool 31 can be used.

The method can be used to manufacture a cooling device 1 for cooling components 2, which has a base section 4 with a first surface 3, and a cooling structure comprising cooling projections 6, which cooling structure protrudes beyond a second surface 5 on the base section 4. At least individual of the cooling projections 6 can have a higher density in the head region than the remaining cooling projections 6 and/or at least individual of the cooling projections 6 can have a different shape in the head region than the remaining cooling projections 6.

The exemplary embodiments show possible embodiment variants, wherein it should be noted in this respect that the invention is not restricted to these particular illustrated embodiment variants of it, but that rather also various combinations of the individual embodiment variants are possible and that this possibility of variation owing to the teaching for technical action provided by the present invention lies within the ability of the person skilled in the art in this technical field.

The scope of protection is determined by the claims. However, the description and the drawings are to be adduced for construing the claims. Individual features or feature combinations from the different exemplary embodiments shown and described may represent independent inventive solutions. The object underlying the independent inventive solutions may be gathered from the description.

Finally, as a matter of form, it should be noted that for ease of understanding of the structure, elements are partially not depicted to scale and/or are enlarged and/or are reduced in size.

1. A method of manufacturing a cooling arrangement for power electronic components, comprising the steps
provisioning a powder-metallurgical substance and forming or pressing the substance to a green compact,
sintering the green compact to a preform,
shaping the preform to a cooling device with an enlarged-surface cooling structure, the enlarged-surface cooling structure comprises a plurality of cooling projections, the cooling projections formed via a pressure-loadable die by pressing a sub-section of the preform into form-defining recesses of the die while a base section remains, the base section connects the individual cooling projections, and
jointing the cooling device via a material bond to a metal cast component by welding or soldering.

2. The method according to claim 1, wherein the cooling projections are formed via the recesses in the die so as to be cylindrical or cone-shaped.

3. The method according to claim 1, wherein a cavity for a cooling medium is defined or limited, at least in sections, by the metal cast component and that the cooling device is inserted in a wall opening of the metal cast component and this wall opening is closed by the cooling device so as to be liquid-tight without a separate sealing element.

4. The method according to claim 1, wherein the cooling device has a rabbet on its circumference, the rabbet is manufactured by shaping with said die or with another die and is used to be in contact with boundary sections of a wall opening of the metal cast component.

5. The method according to claim 4, wherein the boundary sections of the wall opening are machined before the jointing, by a material bond, with the cooling device, so that an even contact surface for the cooling device is created.

6. The method according to claim 1, wherein end sections of the cooling projections facing away from the base section protrude into a cavity of the metal cast component and that the power electronic component is affixed to the first surface of the base section facing away from the cooling projections.

7. The method according to claim 1, wherein a laser-beam welding device is used for the jointing via a material bond, with which laser-beam welding device a fillet weld between a circumferential lateral surface of the cooling device and the cast component is manufactured.

8. The method according to claim 1, wherein the shaping of the preform to the cooling device is carried out in multiple shaping steps.

9. A cooling arrangement for cooling power electronic components, comprising:
a cooling device as a mounting platform for at least one power electronic component, the cooling device is further affixed at a metal component, wherein the cooling device has a first surface at its base section for mounting the at least one power electronic component and a second surface of the base section located opposite the first surface is provided with a cooling structure having cooling projections,
wherein the base section and the cooling projections comprise a sintered substance, the cooling projections are are shaped from the substance of the base section, the metal component is a cast component and the base section of the cooling device is jointed at the metal cast component by welding or by soldering via a material bond and said jointing via a material bond simultaneously establishes a liquid-tight connection between the cooling device and the cast component.

10. The cooling arrangement according to claim 9, wherein the cooling projections at the second surface of the base section are configured cylindrical or cone-shaped.

11. The cooling arrangement according to claim 9, wherein the metal cast component defines or limits, at least in sections, a cavity for a cooling medium, the cooling device is inserted in a wall opening of the metal cast component and the wall opening is closed by the cooling device so as to be liquid-tight without a separate sealing element.

12. The cooling arrangement according to claim 9, wherein the cooling device has a rabbet at its circumference, the rabbet rests against boundary sections of a wall opening of the metal cast component so as to transmit load and conduct heat.

13. The cooling arrangement according to claim 9, wherein the cast component is an aluminum-diecast component and the sintered substance of the cooling device comprises predominantly aluminum or predominantly copper.

14. The cooling arrangement according to claim 9, wherein at least individual of the cooling projections have a higher density in their head section facing away from the base section than the remaining cooling projections and/or at least individual of the cooling projections have a different shape in the head section than the remaining cooling projections.

15. The cooling arrangement according to claim 9, wherein end sections of the cooling projections facing away from the base section protrude into a cavity of the metal cast component.

16. The cooling arrangement according to claim 15, wherein at least some of the cooling projections have a higher density in their head section facing away from the base section than other of the cooling projections.

17. The cooling arrangement according to claim 15, wherein at least some of the cooling projections have a different shape in the head section than other of the cooling projections.

18. The cooling arrangement according to claim 15, wherein the cooling projections at the second surface of the base section are configured cylindrical or cone-shaped.

19. The cooling arrangement according to claim 15, wherein the sintered substance comprises predominantly aluminum.

20. The cooling arrangement according to claim 15, wherein the sintered substance comprises predominantly copper.
